(19) United States
(12) Patent Application Publication
(10) Pub. No.: US 2022/0356602 A1
(43) Pub. Date: Nov. 10, 2022

(54) IN-SITU AND SELECTIVE AREA ETCHING OF SURFACES OR LAYERS, AND HIGH-SPEED GROWTH OF GALLIUM NITRIDE, BY ORGANOMETALLIC CHLORINE PRECURSORS

(71) Applicant: Yale University, New Haven, CT (US)

(72) Inventors: Jung HAN, New Haven, CT (US); Bingjun LI, New Haven, CT (US)

(21) Appl. No.: 17/620,182

(22) PCT Filed: Jun. 16, 2020
(86) PCT No.: PCT/US2020/037921

§ 371 Date: Dec. 17, 2021

Related U.S. Application Data
(60) Provisional application No. 62/862,906, filed on Jun. 18, 2019.
(60) Provisional application No. 62/863,009, filed on Jun. 18, 2019.

(51) Int. Cl. C30B 29/40; C30B 25/18; C30B 25/16

(52) U.S. Cl. CPC C30B 29/406; C30B 25/186; C30B 25/16

(57) ABSTRACT

Methods and systems for in-situ and selective area etching of surfaces or layers, and high-speed growth of gallium nitride (GaN), by organometallic chlorine (Cl) precursors, are described herein. In one aspect, a method can include exposing a GaN layer or surface to an organometallic Cl precursor within a reactor under conditions sufficient to etch the layer or surface, thereby etching the GaN layer or surface. In another aspect, a method of growing GaN can include inputting a set of reactants comprising at least trimethylgallium (TMGa) and anunonia into an OMVPE reactor; inputting an organometallic Cl precursor into the OMVPE reactor; and reacting the Cl precursor with the TM Ga and with the NH3 to deposit GaN by organometallic vapor phase epitaxy.

### CROSS-REFERENCE TO RELATED APPLICATION(S)

This application claims priority to U.S. Provisional Application Ser. No. 62/862,906, entitled “IN-SITU AND SELECTIVE AREA ETCHING OF SURFACES OR LAYERS BY ORGANOMETALLIC CHLORINE PRECURSORS,” filed Jun. 18, 2019, and U.S. Provisional Application Ser. No. 62/863,009, entitled “HIGH SPEED GROWTH OF GALLIUM NITRIDE BY ORGANOMETALLIC CHLORINE PRECURSORS” filed Jun. 18, 2019, the disclosures of which are incorporated herein by reference in their entirety.

### STATEMENT REGARDING FEDERALLY SPONSORED RESEARCH OR DEVELOPMENT

This invention was made with government support under grant numbers: DEAR0000871 awarded by the Advanced Research Projects Agency—Energy. The government has certain rights in the invention.

### BACKGROUND OF THE INVENTION

Gallium Nitride (GaN) has a great potential in high-power and high-frequency applications. Currently, GaN-based high-electron-mobility transistors (HEMTs) have been deployed for RF power amplification for both commercial and military applications. In order to take the advantage of the merits of GaN material properties, other device structures, including current-aperture vertical electron transistors (CAVETs), junction-barrier Schottky (JBS) diodes, super junction (SJ) devices require the ability to form lateral junctions. However, unlike silicon (Si), in which lateral junctions can be achieved by ion-implantation and dopant diffusion processes, these two techniques for GaN have yet to succeed.

Some conventional methods have been developed to etch GaN. However, each of these conventional methods has various issues. Chlorine (Cl)-based plasma etching, or dry etching, method is a well-established to acquire an anisotropic profile in GaN with a high aspect ratio and nearly vertical sidewall. Dry etching induces the creation of ionized molecules, energetic radicals, and UV photons to break the strong gallium-nitrogen bonds and to remove gallium atoms via the formation of volatile products. However, dry etching induces damage that greatly inhibit device performance. For example, the damage can include plasma-induced damage by photons, radicals, and ions, as well as nitrogen deficiency and impurities on the surface and in the near-surface region. High-temperature annealing in nitrogen and ammonia ambient and wet chemical treatment can mitigate the damage. However, using the above-mentioned methods still does not generate a defect-free regrowth interface.

Conventional wet chemical-based etching methods, including hot potassium hydroxide (KOH) and hot phosphoric acid (H₃PO₄), can selectively attack c-plane GaN surfaces around dislocations and form pits and surface depressions. Further, pulsed-photo-electrochemical (PEC) etching methods can also achieve high aspect ratio trenches, but the surface is rough and can include bumps around dislocations which are due to shorter carrier lifetimes.

Vapor-phase etching in organometallic vapor-phase epitaxy (OMVPE) reactors (or in-situ etching), for example with hydrogen gas and hydrochloric acid, were reported. However, hydrogen gas etching requires high temperature and induces surface roughening by gallium droplets. Furthermore, the corrosive nature of hydrochloric acid is not compatible with OMVPE systems.

Further, with the recent advances in bulk GaN substrates, there has been great effort and progress in the development of IGBT-like GaN vertical transistors. The GaN bulk substrates are commercialized mostly using a growth technique called hydride vapor phase epitaxy (HVPE) that is capable of growing GaN at very high (e.g., greater than 100 μm/hour) growth rate to achieve low dislocation densities. However, most of the HVPE growth processes are not scalable (e.g., from single wafer to greater than 50 wafers) and mass production is still a challenge.

Using OMVPE, researchers have grown vertical GaN transistors on bulk GaN substrates. OMVPE is a technique that can produce very versatile Aluminum Gallium Indium Nitride (AlGaInN) heterostructures and junctions, with highly controllable doping, and with very high throughput (e.g., greater than 50 or 100 wafers per run). These flexibilities are not typically available in HVPE. However, to achieve high breakdown voltages, the active region of vertical transistors requires a thick drift layer (e.g., 30-100 μm), which cannot be easily prepared by contemporary OMVPE in which the growth rates seldom exceeds 5 or 10 μm/hour.

### SUMMARY

Methods and systems for in-situ and selective area etching of surfaces or layers, and high-speed growth of gallium nitride (GaN), by organometallic chlorine (Cl) precursors, are described herein. In one aspect, a method can include exposing a GaN layer or surface to an organometallic Cl precursor within a reactor under conditions sufficient to etch the layer or surface, thereby etching the GaN layer or surface.

This aspect can include a variety of embodiments. In one embodiment, the method can further include masking a portion of the GaN layer or surface while etching selectively the unmasked portion of GaN layer or surface by the organometallic Cl precursor. In some cases, the masking can be done with a dielectric mask.

In another embodiment, the exposing can occur at a temperature below 950° C. In another embodiment, the exposing can occur at a temperature at or below 850° C.

In another embodiment, the method can further include controlling ammonia (NH₃) levels within the reactor, thereby controlling the speed of GaN etching. In another embodiment, the method can further include reducing the ammonia levels below the normal level of 25 mbar partial pressure or more used for organometallic vapor phase epitaxy (OMVPE) growth of GaN, in order to increase the etching rate of GaN. In another embodiment, the method can further include reducing the NH₃ levels below the normal level of 25 mbar partial pressure or more used for organometallic vapor phase epitaxy (OMVPE) growth of GaN, in order to reduce the surface roughness during etching.

In another embodiment, the method can further include regrowing GaN on the etched GaN layer or surface after the exposing by OMVPE in the presence of the Cl precursor. In some cases, the regrowth is performed without exposing the etched GaN layer or surface to atmosphere.

In another embodiment, the organometallic Cl precursor can include tertiarybutylchloride (TBCl).

In another embodiment, the exposing can occur at a temperature at or below 750 degrees Celsius.

In another embodiment, the method can further include controlling organometallic Cl levels within the reactor, thereby controlling a speed of the GaN surface or layer etching.

In another aspect, a method of growing GaN can include inputting a set of reactants comprising at least trimethylgallium (TMGa) and ammonia into an OMVPE reactor; inputting an organometallic Cl precursor into the OMVPE reactor; and reacting the Cl precursor with the TMGa and with the NH3 to deposit GaN by organometallic vapor phase epitaxy.

This aspect can include a variety of embodiments. In one embodiment, the method can further include increasing the growth rate of GaN with the introduction of the Cl precursor. In another embodiment, the method can further include increasing the growth rate of GaN by at least 5 times with the introduction of the Cl precursor.

In another embodiment, the method can further include decreasing the gas phase reaction of TMGa with NH₃ based on the inputted Cl precursor. In some cases, the gas phase reaction can produce solid particles that decrease the growth efficiency.

In another embodiment, the Cl precursor can include TBCl.

In another embodiment, the inputted set of reactants does not include hydrochloric acid (HCl).

In another aspect, a method can include inputting a set of reactants including at least TMGa into an OMPVE reactor; inputting a Cl precursor into the OMPVE reactor; and depositing GaN, with a growth rate based at least in part on the inputted Cl precursor, onto a surface or layer in the OMPVE reactor.

### BRIEF DESCRIPTION OF THE DRAWINGS

For a fuller understanding of the nature and desired objects of the present invention, reference is made to the following detailed description taken in conjunction with the accompanying drawing figures wherein like reference characters denote corresponding parts throughout the several views.

FIG. 1 depicts an organometallic vapor-phase epitaxy (OMVPE) reactor according to an embodiment of the invention.

FIGS. 2A and 2B depict an etching process in an OMVPE reactor according to an embodiment of the invention.

FIG. 3 depicts a graph of gallium nitride (GaN) etch rates according to an embodiment of the invention.

FIGS. 4A and 4B depict atomic force microscope (AFM) images of GaN surfaces after 50 nm etching and removal, according to an embodiment of the invention.

FIG. 5 depicts scanning electron microscope (SEM) images of selective area etching (SAE) of silicon dioxide (SiO₂)-patterned GaN trenches at different reactor pressures and ammonia (NH₃) flow rates according to an embodiment of the invention.

FIG. 6 depicts a SEM image of an etched GaN surface without the presence of NH₃ according to an embodiment of the invention.

FIG. 7 provides a graph of in-situ reflectance trace for GaN growths and etchings under a constant reactor pressure of 200 mbar with 2 slm of NH₃ according to an embodiment of the invention.

FIGS. 8A and 8B depict a graph and Arrhenius plot, respectively, of GaN decomposition rates according to embodiments of the invention.

FIG. 9 depicts a graph of NH₃ flow rate vs. measured planar etch rate of GaN according to an embodiment of the invention.

FIGS. 10A and 10B depict cross-section SEM images of SAE results according to embodiments of the invention.

FIG. 11 depicts an OMVPE reactor according to an embodiment of the invention.

FIGS. 12A and 12B depict a prior art deposition process in an OMVPE reactor.

FIG. 13 depicts an image of laser light scattering of GaN OMVPE growth according to Coltrin et al., Modeling the parasitic chemical reactions of AlGaN organometallic vapor-phase epitaxy, J. Cryst. Growth 287, 566 (2006).

FIG. 14 depicts a graph of TMGa flow rate vs. GaN growth rate according to an embodiment of the invention.

FIG. 15 depicts a graph of reactor pressure vs. GaN growth rate according to an embodiment of the invention.

FIG. 16A depicts a graph of photoluminescence (PL) near-band-edge emissions for GaN template samples; and FIG. 16B depicts a graph of x-ray photoelectron spectroscopy for GaN template samples, according to embodiments of the invention.

FIG. 17 is an Atomic Force Microscopy (AFM) image of TBCl-etched bulk GaN template after 300 nm removal under reduced NH₃ flow rate and pressure according to an embodiment of the invention.

FIG. 18 is an AFM image after direct 200 nm unintentionally doped (UID)-GaN regrowth on the bulk GaN template of FIG. 17 surface without breaking vacuum.

FIG. 19 depicts a graph of measured etching depth vs. filling factor of trenches in selective-area etching process (solid line) compared to selective area growth of GaN (dashed line), according to an embodiment of the invention.

### DEFINITIONS

The instant invention is most clearly understood with reference to the following definitions.

As used herein, the singular form “a,” “an,” and “the” include plural references unless the context clearly dictates otherwise.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from context, all numerical values provided herein are modified by the term about.

As used in the specification and claims, the terms “comprises,” “comprising,” “containing,” “having,” and the like can have the meaning ascribed to them in U.S. patent law and can mean “includes,” “including,” and the like.

Unless specifically stated or obvious from context, the term “or,” as used herein, is understood to be inclusive.

Ranges provided herein are understood to be shorthand for all of the values within the range. For example, a range of 1 to 50 is understood to include any number, combination of numbers, or sub-range from the group consisting 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 (as well as fractions thereof unless the context clearly dictates otherwise).

### DETAILED DESCRIPTION OF THE INVENTION

### In-Situ and Selective Area Etching

In certain aspects, the invention provides a system and associated method for in-situ and selective area etching of surface or layers by chlorine (Cl) precursors.

The claimed method results in defect-free etching of surface or layer using an organometallic vapor phase epitaxy (OMVPE) reactor. An organometallic chlorine precursor such as tertiarybutyl-chloride (TBCl) can be used in conjunction with ammonia (NH₃) to conduct vapor-phase etching of a surface or layer, such as a gallium nitride (GaN) surface or layer. The gas flows over the surface or layer and reacts with the molecular composition of the surface or layer, causing components of the surface or layer to decompose and desorb. The use of the organometallic chlorine precursor produces a volatile compound formation when reacting with the surface or layer, where properties of the volatile compound facilitate low-temperature etching. Low-temperature etching can prevent mass transport of the surface or layer. Further, the organometallic chlorine precursor can also facilitate desorption rates of the etching product, thereby mitigating the effects of molecular buildup on the surface caused by a higher decomposition rate compared to the desorption rate. The effects of utilizing organometallic chlorine precursors in OMVPE etching of a surface or layer allow for practical and manufacturable forms of smooth and defect free layer or surface etching.

### OMVPE Reactor

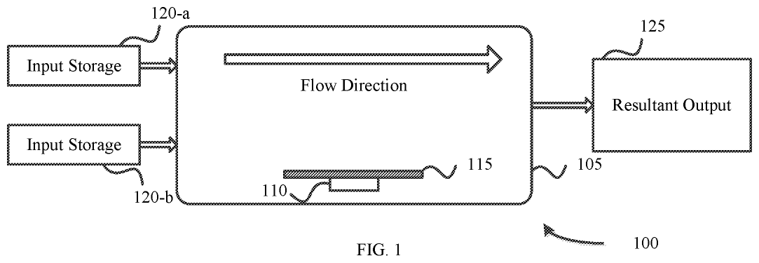

FIG. 1 illustrates an OMVPE reactor 100 according to an embodiment of the claimed invention. The OMVPE reactor can include a chamber 105 where an OMVPE process can occur. The chamber can include connections to an input or multiple inputs 120-a and 120-b for different compounds to enter into the chamber 105, and an output 125 for any resultant compounds to exit the chamber. Further, the chamber's reaction properties, such as temperature and pressure, can be controlled. For example, the temperature and pressure within the chamber 105 can be controlled to create a reaction environment. Additionally, the flow rate of the compounds entering the chamber 105 can be controlled. Each input 120-a and 120-b can include a temperature controller and mass flow controller, which in turn can assist with environmental parameter controls for the chamber 105.

In one embodiment, the OMVPE reactor 100 can include a controller programmed to implement the methods described herein. For example, the controller can be communicatively coupled to one or more valves, sensors (e.g., temperature, pressure, mass-flow, cameras, imagers, and the like), heaters, and the like. The controller can implement one or more algorithms such as a feedback loop to produce and maintain desired reactor conditions for a specified period of time.

The chamber 105 can also include a surface 110 for positioning a surface or layer 115 within the chamber 105. The surface can either be an interior surface of the chamber 105, or can be an elevated surface apart from the chamber 105.

### Surface or Layer

A surface or layer comprising GaN can be positioned within the OMVPE reactor 100. Furthermore, the surface or layer can be a wafer for electronics manufacturing.

### Masking

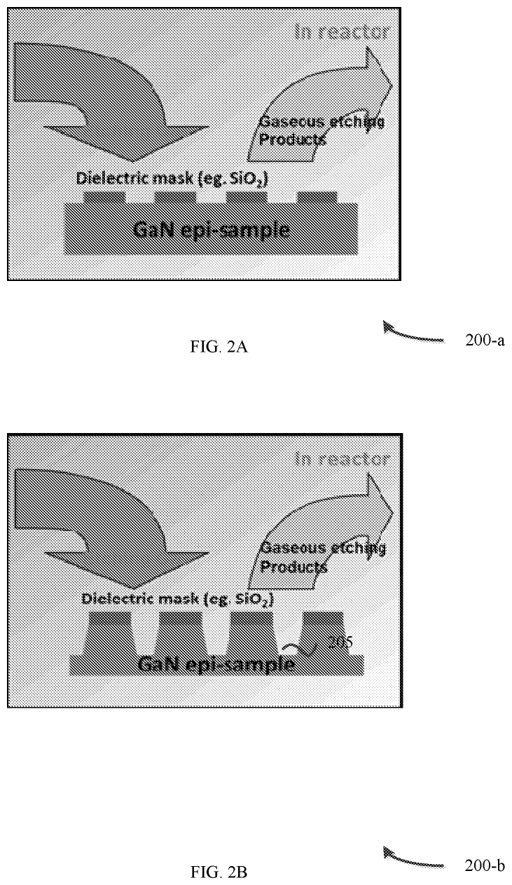

In some cases, a masking substance can be placed on the surface or layer to control the design of the etching. For example, a dielectric material such as silicon dioxide (SiO₂) can be placed on the surface or layer. The dielectric material can resist reacting with the compounds inputted into the OMVPE reactor and, thus, the dielectric material can shield the portions of the surface or layer that the dielectric is placed over from reacting with the inputted compounds. An illustration of a masking of a surface or layer can be seen in FIG. 2. FIG. 2A depicts a preliminary image 200-a of a GaN epi-sample prepped for etching. The mask is placed on top of the GaN epi-sample, thus exposing other portions of the GaN epi-sample to the etching gas. FIG. 2B illustrates a resulting image 200-b of the GaN epi-sample undergoing the OMVPE process described in more detail below. The exposed surface of the GaN epi-sample is etched by the etching gas, whereas the GaN epi-sample surface covered by the mask remains intact. This masking can thus lead to selective etching. In this example, the etching generates a set of trenches 205 within the surface or layer.

### Carrier Gas

A carrier gas can be used in the OMVPE reactor to carry the organometallic chlorine precursor into the reactor. The carrier gas can be an example of one of the input compounds 120-a and 120-b as described in more detail with reference to FIG. 1. The examples provided implement hydrogen gas (H₂) as the carrier gas. However, other carrier gases, such as nitrogen, argon, helium, can also be used. Further, the carrier gas can be purified to remove any impurities that may cause unintentional reactions within the OMVPE chamber. Additionally, in some cases the carrier gas can also be used in conjunction with the organometallic chlorine precursor to etch the layer or surface.

### Organometallic Precursor

An organometallic chlorine precursor can be used to perform the etching of the surface or layer. The below examples implement TBCl as the organometallic precursor. However, other chlorine-based precursors can be used, such as such as chloromethane (CH₃Cl), ethyl chloride (C₂H₅Cl), isopropyl chloride (C₃H₇Cl), chlorobutane (C₄H₉Cl), dichloroethane (C₂H₄Cl₂), methylene chloride (CH₂Cl₂), trichloroethane (C₂H₃Cl₃), chloroform (CHCl₃), arsenic trichloride (AsCl₃), phosphorus trichloride (PCl₃), vanadium chloride (VCl₃), carbon tetrachloride (CCl₄), tetrabromethane (CBr₄), carbon bromotrichloride (CCl₃Br), and the like. The organometallic precursor can be carried into the reaction chamber by the carrier gas. The organometallic precursor can then react with the environment within the reaction chamber, with other compounds within the reaction, or both, to produce a compound (e.g., HCl) for etching the surface or layer. The produced compound can then react with the surface or layer, causing components of the surface or layer to decompose and desorb from the surface. The chlorine-based precursor can facilitate the desorption rate of the surface or layer at lower temperatures, allowing for a more practical etching process. For example, in some cases, surface or layer etching can occur below 950° C. (e.g., between about 650° C. and about 950° C., between about 700° C. and about 950° C., between about 750° C. and about 950° C., and the like). In some cases, surface or layer etching can occur below 850° C. (e.g., between about 650° C. and about 850° C., between about 700° C. and about 850° C., between about 750° C. and about 850° C., and the like). Additionally, the increased desorption rate assists in a smooth etched surface or layer, as this mitigates the potential for decomposed products accumulating on the surface or layer.

### NH₃ Level Control

Notably, the levels of NH₃ levels in the reactor can be controlled to indirectly control the surface or layer etching rate and etching results. For example, in some cases the surface or layer underwent a deposition phase prior to the etching phase, where the deposition phase also includes NH₃ levels within the reactor. The deposition phase may utilize a higher level of NH₃ within the reactor compared to a sufficient amount for the etching process. By reducing the NH₃ levels within the reactor (e.g., below a normal level of 25 mbar partial pressure or more used for OMVPE growth) for the etching phase, the etch rate, the surface smoothness, or a combination thereof, can be increased. Further, the etching process can also be followed by a deposition process, in which case NH₃ levels within the reactor can be increased for sufficient surface or layer deposition. These processes can in some cases occur without exposing the surface or layer to the atmosphere (e.g., not breaking the chamber vacuum of the reactor). In some cases, the NH₃ levels can be controlled through mass-flow input controls.

GaN Surface or Layer with TBCl Precursor

An exemplary embodiment provides for GaN surface or layer etching using TBCl in an OMVPE reactor.

An organometallic precursor, TBCl, is first introduced into the OMVPE reactor for GaN epitaxy. Below is a near-equilibrium reaction, where the forward reaction (to the right) is the process of deposition of GaN during hydride vapor phase epitaxy used for high-speed growth of GaN. The backward (to the left) reaction is the etching of GaN by HCl, which in the claimed invention involves the use of TBCl as the precursor for HCl. An advantage of using TBCl in etching is the formation of volatile gallium chloride (GaCl), which can desorb at relatively low temperature and facilitate low-temperature etching.

GaCl+NH₃ [symbol] GaN+HCl+H₂

Also, in the etching process (leftward reaction), the amount of NH₃ becomes a very sensitive variable that can assist in controlling the etching process that is not typically available in other etching processes.

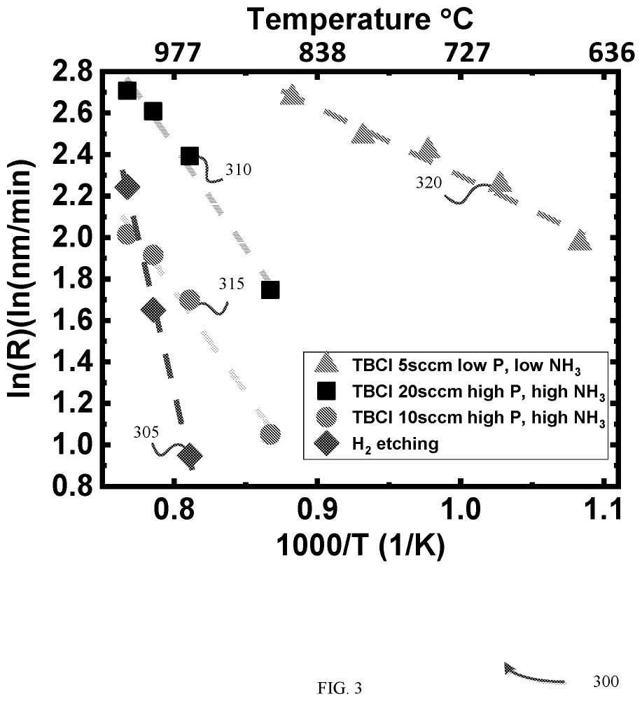

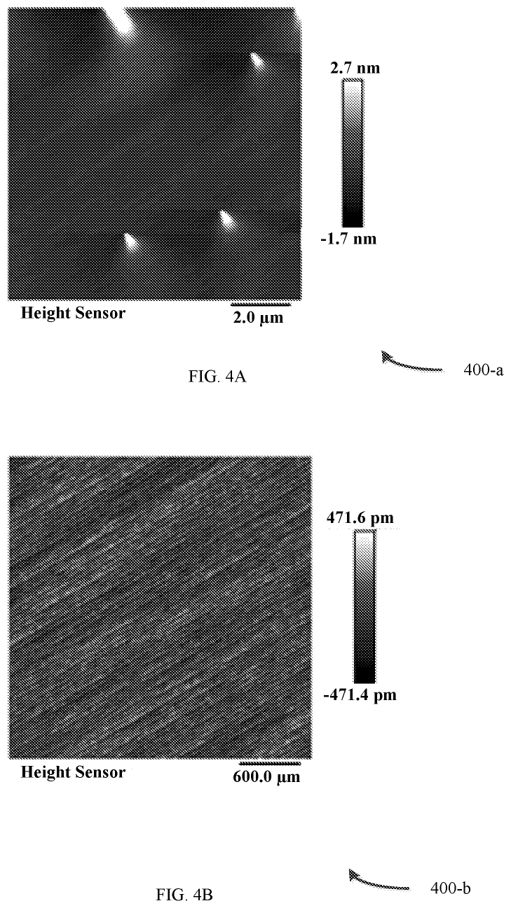

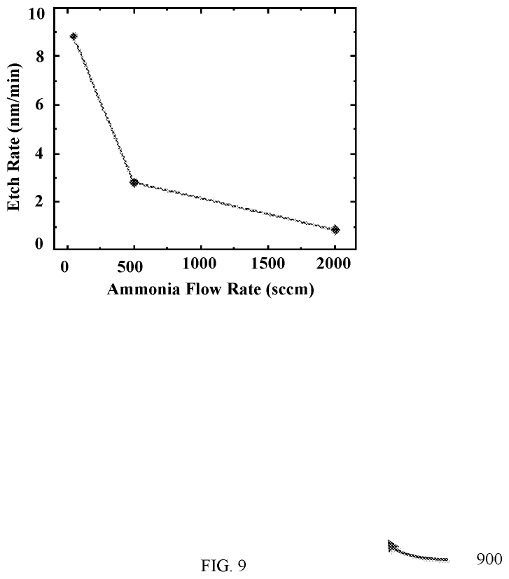

FIG. 3 depicts a graph 300 of etching rate measurements of GaN under different conditions. Conventional in-situ H₂ etching (data points in diamonds 305) works only at elevated temperature, which has side effects including surface degradation and impurity incorporation at high temperatures. However, assisted by TBCl, the etch rate is significantly enhanced at low temperature (circle and square data points 315 and 310). After reducing the NH₃ flow rate and reactor pressure, plausible rates at even lower temperatures (e.g., 650° C. to 850° C.) were measured (for example, data points in triangles 320). Lower temperature for the annealing or the etching process can also prevent mass transport. Mass transport of GaN results in GaN deposition at the trench edge, which introduces unintentional doping due to different impurity incorporation efficiency to different facets and associated vulnerability in the device breakdown. Surface roughing after H₂ etching is another concern. Due to the higher GaN decomposition rate than Ga desorption rate, Ga accumulated on the surface can serve as a catalyst for GaN decomposition and surface roughness. The product of TBCl decomposition, HCl, can remove Ga droplets instantly from the surface or layer and results in layer-by-layer removal and an atomically smooth surface. FIGS. 4A and 4B depict images 400-a and 400-b, respectively, of the atomically smooth surface produced using TBCl as measured by atomic force microscopy (AFM) after 50 nm etching and removal under high NH₃ partial pressure and reactor pressure. FIG. 9 depict an anatomically smooth surface after 300 nm etching and removal under a much lower NH₃ partial pressure and reactor pressure.

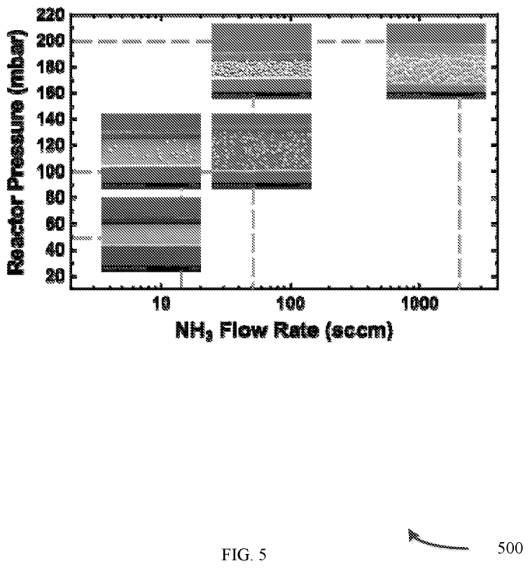

Under appropriate etching conditions, TBCl can also be used for in-situ selective area etching (SAE) which is expected to be of great importance in making GaN junction devices including JBS diodes, super junctions, heterojunction bipolar transistors, and buried heterojunction lasers, and the like. FIG. 5 depicts SEM images 500 of selective area etching of SiO₂-patterned GaN trenches at different reactor pressures and NH₃ flow rates. As can be seen, the pressure and NH₃ flow rate during TBCl etching play an important role in the etching quality. Lowering the pressure and NH₃ flow can drive the etching reaction, increasing the etching rate significantly beyond what is depicted in FIG. 3. At a reduced reactor pressure (e.g., 50 mbar) and NH₃ flow rate (e.g., 14 standard cubic centimeters per minute (sccm)), an etching rate of 50 nm/min at 800° C. results in a smooth surface, as shown in the bottom left image of FIG. 5. Etching pits and hillocks are nonexistent, although dislocation density of the sample can be ˜5×10⁹ cm⁻². The etching remains at near equilibrium and tends to follow crystallographic planes, resulting in anisotropic etching.

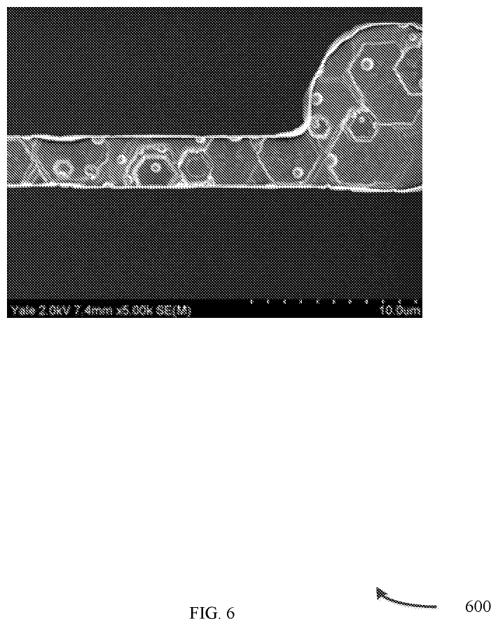

NH₃ plays an important role in regulating the etching reaction and preventing the formation of Ga droplets on the surface. FIG. 6 illustrates the results of GaN etching without NH₃. The SEM image 600 of FIG. 6 illustrates the presence of Ga droplets on the GaN surface after GaN etching, along with surface roughening due, in part, to the Ga droplets.

### Experimental Results

In this study, an alternative Cl-precursor, TBCl, was introduced into a GaN OMVPE reactor for the first time. This enables SAE and SAG to happen both inside the reactor without exposing the etched interface to the environment. Planar etch rates within a range of temperature, TBCl flow rate and NH₃ flow rate are reported. SAE results using SiO₂ dielectric masking are also reported.

C-plane (0001) GaN samples on sapphire substrates using a two-step growth process and on bulk GaN substrates were grown in a horizontal OMVPE reactor. Trimethylgallium (TMGa), TBCl, and NH₃ were used as precursors for Ga, Cl, and N, respectively. Planar etch rate calibration under different conditions were carried out by using in-situ reflectometry (wavelength=550 nm in vacuum) on GaN-on-sapphire samples. This enabled several etching conditions to be tested within one run, after 1 μm unintentionally-doped (UID) GaN being grown on sapphire at 1030° C., and 200 mbar with 2 standard liter per minute (slm) of NH₃ and a TMGa flow rate of 106 μmol/min. To prevent the surface roughness from hindering the accuracy of the measurement, around 60 nm GaN was removed during the etching under certain conditions (¼λ, wavelength in GaN), and mostly more than 100 nm of high-temperature GaN (˜1000° C.) was regrown to recover/smoothen the surface. Selective-area etching experiments were performed on a 2 μm c-GaN grown on Sapphire. A 100 nm thick SiO₂ mask was deposited on the GaN sample by a plasma-enhanced chemical vapor deposition (PECVD) system. Photolithography and reactive-ion etching (ME) were used to pattern the SiO₂ and expose GaN within the openings. SEM was used to study the surface morphology.

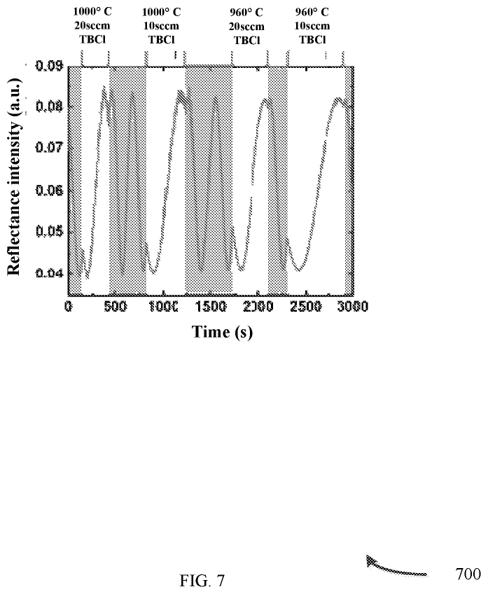

FIG. 7 shows a graph 700 of in-situ reflectance trace for growths and etchings under a constant reactor pressure of 200 mbar with 2 slm of NH₃. TBCl flow rate was varied from 10 to 20 standard cubic centimeter per minute (sccm) while the etching temperature spanned the 960-1000° C. range. Specific conditions are labeled in FIG. 7. No significant decay of the average reflectance intensity was observed in all experiments, indicating smooth surface was maintained during the tests.

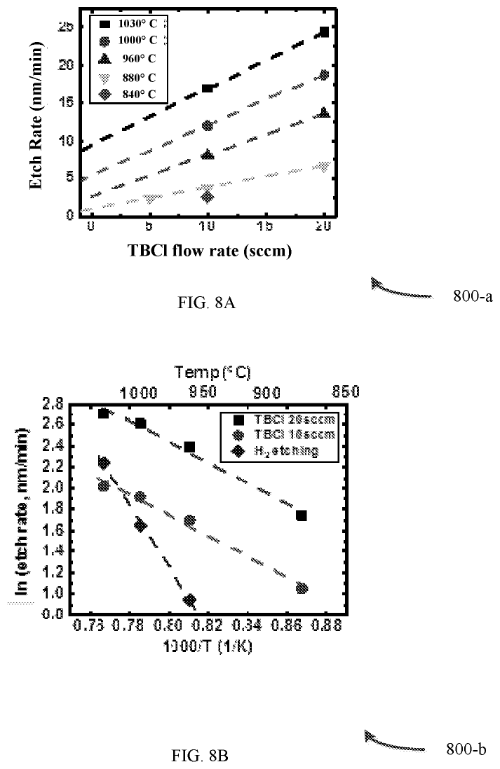

A graph 800-a of decomposition rates with constant NH₃ flow rate of 2 slm and reactor pressure of 200 mbar, is provided in FIG. 8A. Etch rates were linearly increasing with TBCl flow at a constant temperature. H₂ decomposes GaN above 800° C. Based on this, Applicant assumed there are two independent and co-existing etching mechanisms here. The first is H₂ etching and the second could be related to the decomposition of GaN induced by TBCl. Under a specific temperature, etch rate by H₂ can be extracted from a linear extrapolation to the y-axis, corresponding to 0 sccm of TBCl, as shown in the graph 800-a of FIG. 8A. Decomposition rate of GaN, caused by only TBCl, can be estimated by the difference between etch rate and the y-intercept. The rate of two decomposition mechanisms in the form of the Arrhenius plot 800-b is shown in FIG. 8B. An activation energy of 2.57 eV was extracted for H₂ etching using the y-intercept, which is consistent with the decomposition rate measured without TBCl, within a similar temperature range (960-1030° C.). The decomposition rate was limited by N₂ formation and desorption, equal to the formation energy of N vacancy. In addition, the activation energy is the same for both 10 and 20 sccm TBCl flow rates under 200 mbar with 2 slm of NH₃, which is 0.85 eV. It is hypothesized that the etching process was limited by the surface process of desorption of GaCl complexes; alternatively, the decomposition of TBCl to form Cl-radicals can potentially limit the etching process. Because these experiments were performed at more elevated temperatures, compared with other GaN etching experiments, decomposition of TBCl should not be rate-limiting. Therefore, etching induced by TBCl occurred in a GaCl desorption-limited regime.

During the etching experiment, NH₃ and H₂ were flowing simultaneously with TBCl as mentioned earlier. Due to the higher bonding energy in H—Cl (4.4 eV) than Cl—Cl (2.48 eV), formation of HCl is thermodynamically favorable. Then, the following two reactions are the possible etching mechanisms of GaN by TBCl.

(CH₃)₃CCl+H→(CH₃)₃C+HCl_{(g)} (1)

GaN+HCl_{(g)}+H₂_{_{(g)}} [symbol] GaCl_{(g)}+NH₃_{_{(g)}} (2)

The second reaction is reversible. The forward reaction represents the etching process, while the reverse reaction is the reaction used in hydride vapor phase epitaxy (HVPE) of GaN, where GaCl is formed by HCl flowing through a heated liquid Ga source and injected together with NH₃ to the reactor with a growth rate of GaN around 100 μm/h. Therefore, as shown in the graph 900 of FIG. 9, NH₃ flow rate or partial pressure could greatly modulate the etch rate under a constant TBCl flow rate (5 sccm), temperature (800° C.), and pressure (200 mbar). The etch rate at 2 slm of NH₃ was calculated, first using an extrapolation of the Arrhenius plots in FIG. 8B to get the etch rate with 10 and 20 sccm TBCl flow rate at 800° C., and then using linear relationship between etch rate and TBCl flow rate to extrapolate to 5 sccm of TBCl (H₂ etching was ignored at this temperature). This relationship is also consistent with the one reported in the case of InP etched by TBCl with different PH₃ flow rate.

In addition, the same measurements were performed after lowering the NH₃ flow rate and reactor pressure to, for example, 14 sccm and 50 mbar, respectively, under temperatures ranging from 650° C. to 860° C. The Arrhenius plot 800-b is also shown in FIG. 8B.

Interestingly, ˜7 nm/min etch rate was observed at 650° C., at which GaN is not supposed to decompose without TBCl.

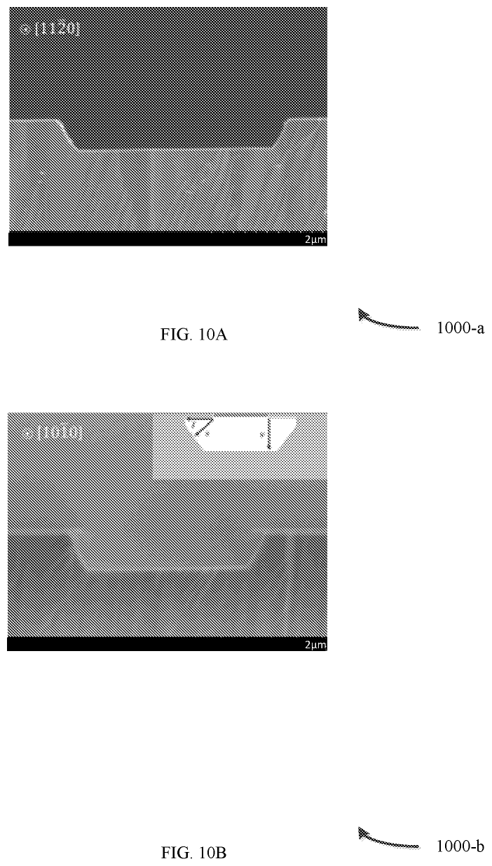

Selective-area etching was first performed using 2 slm of NH₃, 10 sccm of TBCl under 840° C. and reactor pressure of 200 mbar, with a planar etch rate of 2.5 nm/min. As shown in the SEM images 500 of FIG. 5, large pyramids presented in the trench (˜3 μm width) after 40 min etching with a depth of ˜800 nm (cross-section SEM is not shown). Greatly enhanced etch rate can be due to the lateral diffusion, the same as the case of selective-area growth. The origin of these pyramids, as mentioned in the case of InP, was due to the low desorption rate of etching products, resulting in a local inhibition of etching process. Therefore, by reducing reactor pressure and NH₃ flow rate, pyramids density and size were reduced. They disappeared and smooth surface was achieved under SEM with NH₃ flow rate of 14 sccm and 2.5 sccm of TBCl at 800° C. and 50 mbar with a vertical etch rate of 50 nm/min. The cross-section SEM images 1000-a and 1000-b of stripe-patterns are shown in FIGS. 10A and 10B, in both a and m directions, respectively. The sidewalls are confined by mainly two facets {101̅1} and {112̅2}. In SAG and SAE study, the growth or etch rate was determined by the linear dimension from the edge of mask to a facet of interest (shown in the inset of FIG. 10B). The etch rate comparison

R{112̅2}>R{101̅1}

was clear from the cross-section SEM images 1000-a and 1000-b. This etch rate anisotropy can be explained by the atom arrangements on the surface, where {112̅2} is Ga-polar plane, and HCl or Cl radicals preferentially stick to this surface with the formation of III-Cl species, while {101̅1} is N-polar plane.

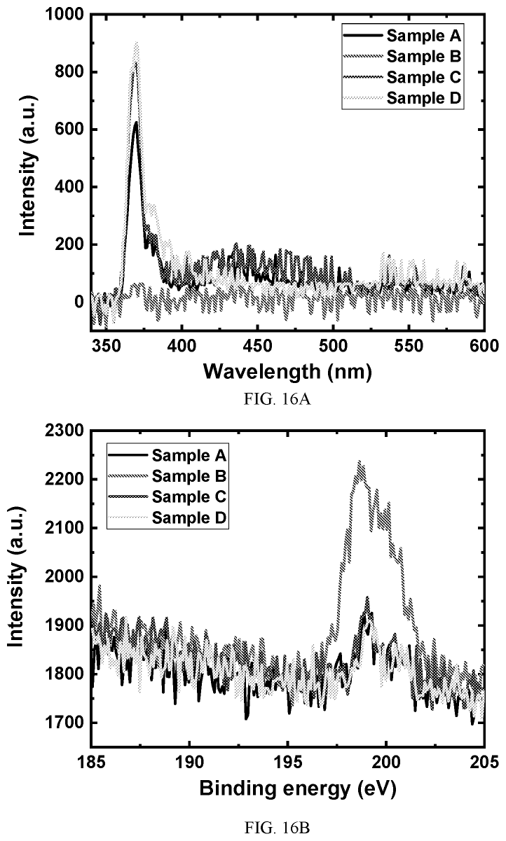

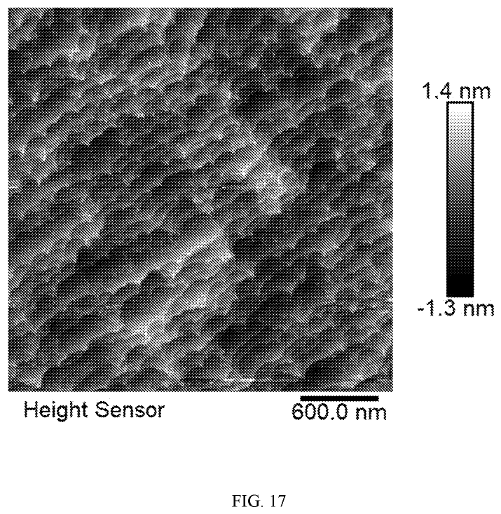

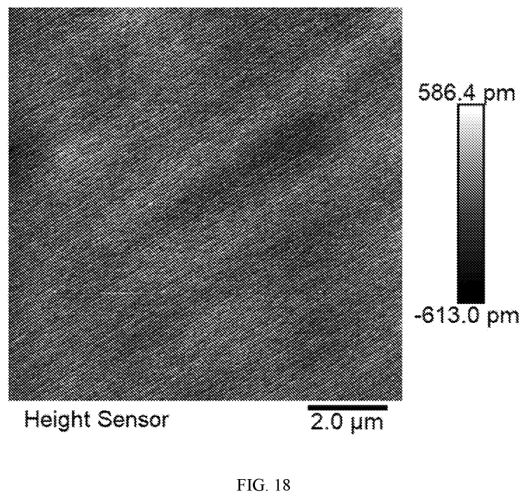

Since dislocations, especially the screw type ones, are detrimental to the device performance, bulk GaN with low dislocation density can be used. Under the pyramid-free etching condition, TBCl etching was performed on 1.5 μm UID-GaN templates grown on bulk GaN substrate. Four samples are compared here. Detailed processes are listed in Table 1. Sample A is a template. Sample B-D are templates etched by Cl-based plasma, TBCl and a combination of both, respectively. Photoluminescence (PL) showed strong near-band-edge emissions only from Sample A, C and D (FIG. 16A). Only Sample B had obvious Cl peak from x-ray photoelectron spectroscopy (XPS) (FIG. 16B). Both PL and XPS confirm that TBCl etching is able to remove the impurity and damage induced by plasma etching and does not introduce damage itself. AFM image of TBCl-etched surface (Sample C) is shown in FIG. 17, indicating atomic smoothness is maintained during the process. These results show that in situ TBCl etching can serve as an alternative etching method without plasma etching damage, or help remove the plasma etching damage. Regrowth of unintentionally doped GaN (200 nm thickness) was performed on TBCl etched template without breaking the vacuum, and atomically smooth surface is observed under AFM, shown in FIG. 18.

TABLE 1
Processes on Samples A-D

| | 300 nm plasma etching | 300 nm TBCl etching |
|---|---|---|
| Sample A | | |
| Sample B | x | |
| Sample C | | x |
| Sample D | x | x |

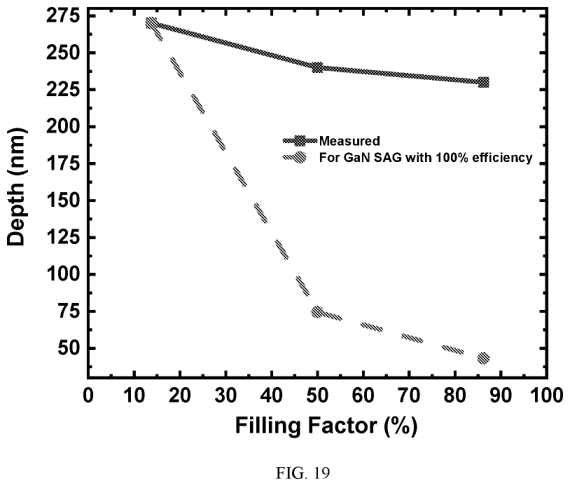

Selective-area etching under the same pyramidal-free condition was performed on GaN template grown on bulk GaN substrate. We found there is a little dependence of etching depth on the filling factor of trench patterns, as shown in solid-line of FIG. 19. This behavior is in a great contrast to the selective-area growth, where the accumulation of laterally diffused Ga significantly enhances the growth rate in the trench (dash-line in FIG. 19).

In summary, the planar etch rate of GaN by TBCl was measured by in-situ reflectometry at a range of temperatures, TBCl and NH₃ flow rates. Activation energies were extracted and etching mechanisms were discussed. Selective-area etching was also studied. Pyramids within the trenches, caused by etching residue, were eliminated by reducing the reactor pressure and NH₃ flow rate. The final structures of the etched stripe-trenches were bounded by well-defined crystallographic facets due to the anisotropic etch rate from cross-section SEM images. The atomically smooth etched-surface, without plasma-induced damage and impurities, as confirmed by XPS and PL results, is promising for the further applications to the subsequent selective area doping using regrowth approach in many GaN-based device structures. Trenches and regrowth will happen both inside the OMVPE reactor, without breaking the chamber vacuum, which further prevents contamination to the regrowth interface from surrounding environments.

### High Speed Growth of GaN

In other aspects, the invention provides a system and associated method for growth, regrowth, and selective area growth of surface or layers by organometallic chlorine precursors.

The claimed method results in quick and non-corrosive deposition of surface or layer using an OMVPE reactor. An organometallic Cl precursor such as TBCl can be used in conjunction with NH₃ and TMGa to conduct vapor-phase deposition of a surface or layer, such as a GaN surface or layer. Inputted gas diffuses to the surface or layer and reacts with the molecular composition of the surface or layer, causing components of the inputted gas to deposit onto the surface or layer. The use of the organometallic Cl precursor allows for at least a portion of the TMGa to react with the Cl precursor, to form a new product (e.g., GaCl). This product can then, in turn, react with the NH₃ to produce GaN growth. The Cl precursor can, therefore, mitigate the disadvantages of TMGa reacting with the NH₃, such as gas phase reactions that produce solids accumulating on the surface or layer. The effects of utilizing organometallic Cl precursors in OMVPE deposition of surface or layer allow for practical and manufacturable forms of surface or layer deposition.

### OMVPE Reactor

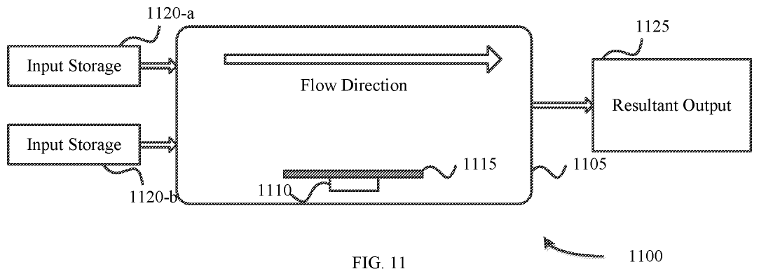

FIG. 11 illustrates an OMVPE reactor 1100 according to an embodiment of the claimed invention. The OMVPE reactor can include a chamber 1105 where an OMVPE process can take place. The chamber can include connections to an input or multiple inputs 1120-a and 1120-b for different compounds to enter into the chamber 1105, and an output 1125 for any resultant compounds to exit the chamber. Further, the chamber's reaction properties, such as temperature and pressure, can be controlled. For example, the temperature and pressure within the chamber 1105 can be controlled to create a reaction environment for surface or layer growth or regrowth (e.g., maintaining a temperature between 700 degrees Celsius to 1,100 degrees Celsius). Additionally, the flow rate of the compounds entering the chamber 1105 can be controlled. Each input 1120-a and 1120-b can include a temperature controller and mass flow controller, which in turn can assist with environmental parameter controls for the chamber 1105.

The chamber 1105 can also include a surface 1110 for positioning a surface or layer 1115 within the chamber 1105. The surface 1110 can either be an interior surface of the chamber 1105, or can be an elevated surface apart from the chamber 1105.

In one embodiment, the OMVPE reactor 1100 can include a controller programmed to implement the methods described herein. For example, the controller can be communicatively coupled to one or more valves, sensors (e.g., temperature, pressure, mass-flow, cameras, imagers, and the like), heaters, and the like. The controller can implement one or more algorithms such as a feedback loop to produce and maintain desired reactor conditions for a specified period of time.

### Surface or Layer

Various types of surface or layers can be positioned within the OMVPE reactor 1100. The below examples discuss the use of GaN. However, other surface or layers can be used as well, such as silicon (Si), silicon carbide (SiC), sapphire, and the like. Furthermore, the surface or layer can be a wafer for electronics manufacturing.

### Carrier Gas

A carrier gas can be used in the OMVPE reactor to carry the organometallic Cl precursor into the reactor. The carrier gas can be an example of one of the input compounds 1120-a and 1120-b as described in more detail with reference to FIG. 11. The examples provided implement hydrogen gas (H₂) as the carrier gas. However, other carrier gases, such as nitrogen, argon, and helium, can also be used. Further, the carrier gas can be purified to remove any impurities that may cause unintentional reactions within the MOVDC chamber.

### Organometallic Precursor

An organometallic precursor can be used during the deposition process to provide necessary components in surface or layer growth. For example, the organometallic precursor can in some cases react with other compounds within the OMVPE reactor to deposit onto the surface or layer. Additionally or alternatively, the organometallic precursor can react with the environmental surroundings within the OMVPE reactor (e.g., pyrolysis, etc.) to deposit onto the surface or layer. The below examples rely on TMGa as an organometallic precursor. However, other organometallic precursors can be used as well, such as trimethylaluminum (TMAl, AlMe₃), trimethylindium (TMIn), triethylgallium (TEGa) and the like.

### Conventional Deposition Process of GaN

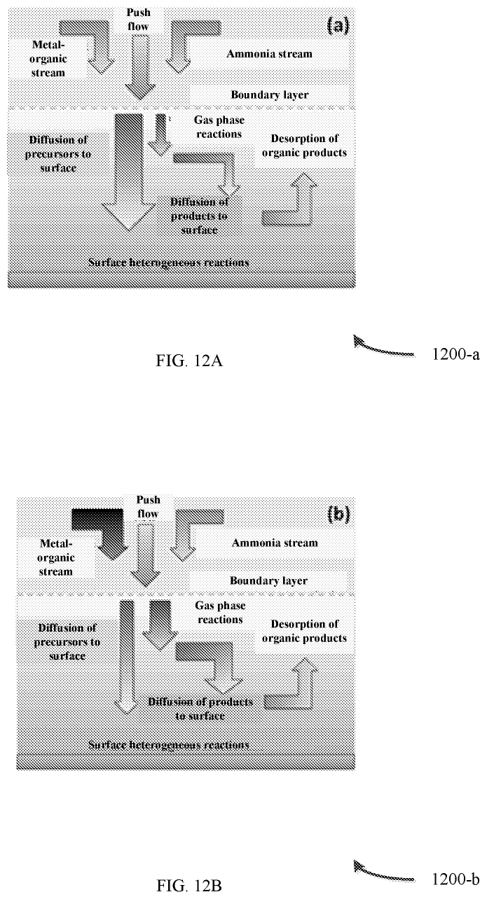

It is generally accepted that the growth rate for AlGaInN OMVPE is limited to about 10 μm/hr. One cause of this limitation is the depletion of organometallic precursors, such as TMGa or TMA, due to gas phase parasitic reaction and aggregation under high organometallic partial pressures. FIG. 12 illustrates conceptually the two scenarios during OMVPE growth. For the conventional OMVPE growth of GaN, TMGa, at a modest partial pressure (shown in FIG. 12A), and NH₃ are introduced along with carrier gases (H₂ and/or N₂) at room temperature. The precursor gases become heated as they enter into the boundary layer and diffuse toward the heated wafer surface. Ideally, the majority of the precursors diffuse through the boundary layer and undergo pyrolysis followed by surface reaction and incorporation. There is also a small degree of gas-phase parasitic reaction, such as the formation of dimers of GaMe₂, but the reaction does not continue further. The growth rate of GaN is primarily determined by the mass-transport of TMGa in the gas phase.

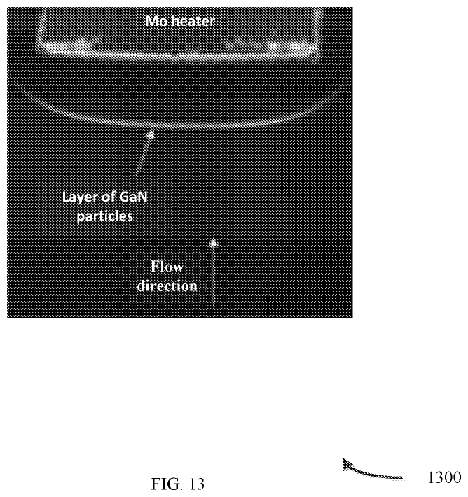

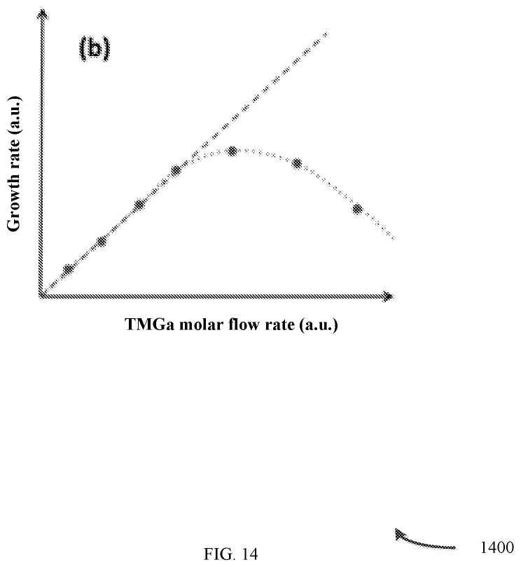

However, as the flow rate of TMGa increases in order to increase the growth rate of GaN (as shown in FIG. 12B), the gas phase parasitic reaction increases proportionally due to increased intermolecular collision rates in the gas phase, and the TMGa dimers can quickly polymerize to form nuclei e.g., (approximately on the order of magnitude of 100 atoms) and then nano-particles in the gas phase. The presence of nanoparticles during GaN OMVPE growth has been directly observed by laser light scattering, as shown in the image 1300 of FIG. 13. With the increase of partial pressure of TMGa at the inlet, a high density of particles under high super-saturation will lead to a runaway condition where the majority of metalorganic precursors will no longer diffuse in the molecule form on the surface but will precipitate as solid particles, leading to saturation, if not a decrease, in the growth rate, as shown in the graph 1400 of FIG. 14.

### Organometallic Cl Precursor

An organometallic Cl precursor can be used to increase growth rates of the surface or layer. The below examples implement TBCl as the organometallic Cl precursor. However, other halogen-based precursors can be used, such as CH₃Cl, C₂H₅Cl, C₃H₇Cl, C₄H₉Cl, C₂H₄Cl₂, CH₂Cl₂, C₂H₃Cl₃, CHCl₃, AsCl₃, PCl₃, VCl₃, CCl₄, CBr₄, CCl₃Br, and the like. The organometallic Cl precursor can be carried into the reactor chamber by the carrier gas. The organometallic Cl precursor can then diffuse towards the surface or layer. The organometallic Cl precursor can react with the environment of the reaction chamber, and/or react with other compounds placed within the reaction chamber. For example, in some cases the organometallic Cl precursor can pyrolyze at suitable temperature and pressure of the reactor chamber and break down into different components required for surface deposition. In some cases, the organometallic Cl precursor can react with, for example, another organometallic precursor to produce a compound required for surface or layer deposition.

The organometallic Cl precursor can also facilitate surface or layer etching of GaN at lower temperatures in the absence of gallium precursors. For example, in some cases, GaN etching can occur between 700° C. and 1100° C. (e.g., between about 700° C. and about 800° C., between about 800° C. and about 900° C., between about 900° C. and about 1000° C., and the like).

### NH₃ Level Control

In some cases, levels of NH₃ levels in the reactor can be controlled to indirectly control the surface or layer growth rate. For example, in some cases the surface or layer underwent an etching phase prior to the deposition phase, where the etching phase also includes NH₃ levels within the reactor. The etching phase may utilize a lower level of NH₃ within the reactor compared to a sufficient amount for the deposition process. Further, the deposition process can also be followed by an etching process, in which case NH₃ levels within the reactor can be decreased for sufficient surface or layer etching. These processes can in some cases occur without exposing the surface or layer to the atmosphere (e.g., not breaking the chamber vacuum of the reactor). The NH₃ levels can be controlled in some cases through mass-flow input controls.

### Experimental Results

The use of a OMVPE-compatible Cl precursor, TBCl, is proposed as a substituting reactant to transform the standard GaN OMVPE process into a “HVPE-like” environment, yet without the hazard and problems that are typically associated with HCl (e.g., the corrosive nature of HCl). TBCl has been used in the III-V (e.g., GaAs and InP) OMVPE for regrowth of buried-heterostructure laser diodes and for selective area growth.

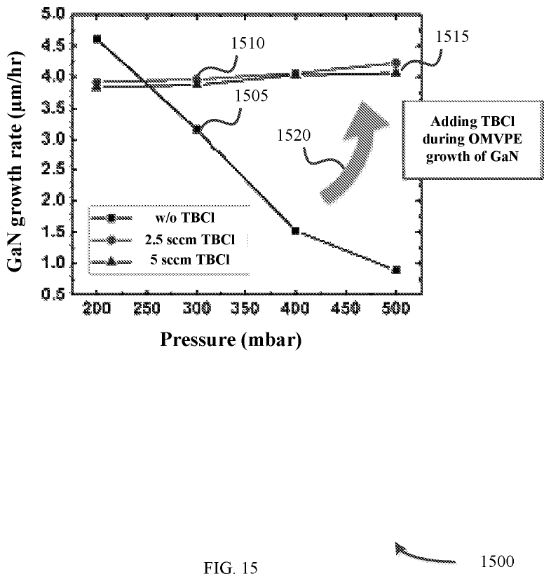

A series of experiments were performed to test this theory and to demonstrate the possibility of breaking through the barrier related to gas phase reactions. The flow rate of TMGa was set to a maximum of 48 sccm, which produces a growth rate of around 4.6 μm/hr in the absence of any gas phase reaction. The increase of TMGa was simulated by increasing the total reactor pressure from 200 to 500 mbar, and the partial pressure of TMGa will increase accordingly given all the flows (NH₃=2 SLM, H₂=6 SLM) are held constant during the OMVPE process. FIG. 15 shows that increasing the reactor pressure caused a dramatic decrease of the growth rate of GaN from 4.6 to below 1.0 μm/hr, as determined by in-situ reflectometry. This is shown as the square data points 1505 in FIG. 15, adding merely 2.5 or 5.0 sccm of TBCl during the same growth process, conversely, leads to a dramatic increase of the growth rates, shown as the circle and triangle data points 1510 and 1515, respectively. This increase is highlighted by the curved arrow 1520 in FIG. 15. The fact that the growth rates of GaN in the presence of TBCl becomes pressure-independent gives a strong proof that TBCl has reacted with TMGa and now the growth of GaN is carried out by GaCl reacting with NH₃; an entirely different chemistry is involved now and the growth is no longer subject to the gas phase reactions of TMGa. We also note that the reduction of the growth rates from 4.6 to around 4.0 μm/hr is likely due to a concurrent etching of GaN with TBCl. With the further increase of the TMGa flow, this background etching will become negligible toward truly high growth rate GaN in OMVPE environment.

### EQUIVALENTS

Although preferred embodiments of the invention have been described using specific terms, such description is for illustrative purposes only, and it is to be understood that changes and variations may be made without departing from the spirit or scope of the following claims.

### INCORPORATION BY REFERENCE

The entire contents of all patents, published patent applications, and other references cited herein are hereby expressly incorporated herein in their entireties by reference.

1. A method comprising:
exposing a gallium nitride (GaN) layer or surface to an organometallic chlorine (Cl) precursor within a reactor under conditions sufficient to etch the layer or surface, thereby etching the GaN layer or surface.

2. The method of claim 1, wherein the exposing occurs at a temperature below 950° C.

3. (canceled)

4. The method of claim 1, further comprising:
controlling NH₃ levels within the reactor, thereby controlling the speed of GaN etching.

5. The method of claim 1, further comprising:
reducing NH₃ levels below the normal level of 25 mbar partial pressure or more used for organometallic vapor phase epitaxy (OMVPE) growth of GaN.

6. The method of claim 1, further comprising:
reducing NH₃ levels below the normal level of 25 mbar partial pressure or more used for organometallic vapor phase epitaxy (OMVPE) growth of GaN, in order to reduce the surface roughness during etching.

7. The method of claim 1, further comprising:
regrowing GaN on the etched GaN layer or surface after the exposing by organometallic vapor phase epitaxy (OMVPE) in the presence of the organometallic Cl precursor.

8. The method of claim 7, wherein the regrowth is performed without exposing the etched GaN layer or surface to atmosphere.

9. The method of claim 1, wherein the organometallic Cl precursor comprises tertiarybutylchloride (TBCl).

10. (canceled)

11. The method of claim 1, further comprising:
controlling organometallic Cl precursor levels within the reactor, thereby controlling a speed of the GaN surface or layer etching.

12. The method of claim 1, further comprising:
masking a portion of the GaN layer or surface while etching selectively the unmasked portion of GaN layer or surface by the organometallic Cl precursor.

13. The method of claim 12, wherein the masking is done with a dielectric mask.

14.-17. (canceled)

18. A method of growing gallium nitride (GaN), the method comprising:
inputting a set of reactants comprising at least trimethylgallium (TMGa) and ammonia (NH₃) into an organometallic vapor phase epitaxy (OMVPE) reactor;
inputting an organometallic chlorine (Cl) precursor into the OMVPE reactor; and
reacting the Cl precursor with the TMGa and with the NH₃ to deposit GaN by organometallic vapor phase epitaxy.

19. The method of claim 18, further comprising:
increasing the growth rate of GaN with the introduction of the Cl precursor.

20. The method of claim 18, further comprising:
increasing the growth rate of GaN by at least 5 times with the introduction of the Cl precursor.

21. The method of claim 18, further comprising:
decreasing the gas phase reaction of TMGa with NH₃ based on the inputted Cl precursor.

22. The method of claim 21, wherein the gas phase reaction produces solid particles that decrease the growth efficiency.

23. The method of claim 18, wherein the Cl precursor comprises tertiarybutylchloride (TBCl).

24. The method of claim 18, wherein the reacting step is performed at a temperature between 700 degrees Celsius to 1,100 degrees Celsius.

25. The method of claim 18, wherein the inputted set of reactants does not include hydrochloric acid (HCl).

26. A method, comprising:
inputting a set of reactants comprising at least trimethylgallium (TMGa) into an organometallic vapor phase epitaxy (OMPVE) reactor;
inputting a chlorine (Cl) precursor into the OMPVE reactor; and
depositing gallium nitride (GaN), with a growth rate based at least in part on the inputted Cl precursor, onto a surface or layer in the OMPVE reactor.
